(19) United States
(12) Patent Application Publication
(10) Pub. No.: US 2012/0139110 A1
(43) Pub. Date: Jun. 7, 2012

(54) TAPE

(75) Inventors: KJ JAN, Hukou (TW); Chien-Hsuan KUO, Hukou (TW); Mu-Sen TNEG, Hukou (TW)

(73) Assignee: POWERTECH TECHNOLOGY INC., Hsinchu (TW)

(21) Appl. No.: 13/313,453

(22) Filed: Dec. 7, 2011

(30) Foreign Application Priority Data
Dec. 7, 2010 (TW) 099142588

(51) Int. Cl. H01L 23/498

(52) U.S. Cl. 257/738; 257/E23.069

(57) ABSTRACT

A tape for carrying at least a semiconductor package structure comprising a body, a carrying plate and a side wall is provided. The body has at least an opening. The carrying plate is capable of carrying the semiconductor package structure and has a plurality of containing portions. The side wall surrounds the carrying plate and connects between the body and the carrying plate. A side surface of the semiconductor package structure leans against the side wall and a plurality of solder balls disposed on a bottom surface of the semiconductor package structure are contained in the containing portion. Accordingly, the solder balls may be protected from being damaged by the carrying plate.

### FIELD OF THE INVENTION

The present invention generally relates to a tape, and more particularly to a tape for carrying a semiconductor package structure.

### DESCRIPTION OF THE RELATED ART

With the development of technology, widths of wires and pitches therebetween in an integrated circuit (IC) are decreased for continuously increasing computing requirement of the electronic apparatus. Further, a ball grid array (BGA) semiconductor package structure is accordingly developed for continuously increasing high integration in IC.

To the BGA semiconductor package structure, solder balls disposed on a bottom of the semiconductor package structure in an array are likely to be damaged or separated from the bottom due to being hit or pressed during shipping and transporting, and thus the whole BGA semiconductor package structure may be inoperable. Therefore, the BGA semiconductor package structure is usually packed well by a tape strip or a tape roll before shipping. In general, the tape has a plurality of containing portions on a body of the tape, which are formed by a pressing process and arranged in a straight line, for containing a plurality of the BGA semiconductor package structures respectively. Therefore, the BGA semiconductor package structures are not only more convenient for shipping and transporting, but also prevented from being damaged or separated due to being hit or pressed during shipping and transporting.

Note that the conventional tape contains each of the BGA semiconductor package structures in one of the containing portions directly without protecting the BGA. Therefore, the solder balls are likely to be damaged or separated from the semiconductor package structure due to being hit or pressed by the conventional tape, and thus the whole BGA semiconductor package structure may be inoperable.

### SUMMARY OF THE INVENTION

The present invention is directed to a tape, which may protect solder balls from being damaged or separated from a bottom surface of a semiconductor package structure due to being hit or pressed.

The present invention provides a tape for carrying at least a semiconductor package structure having a bottom surface, a side surface surrounding the bottom surface and a plurality of solder balls disposed on the bottom surface. The tape comprises a body, at least a carrying plate and at least a side wall. The body has at least an opening. The carrying plate is capable of carrying the semiconductor package structure and has a plurality of containing portions. The side wall surrounds the carrying plate and connects between the body and the carrying plate. The side surface leans against the side wall and the solder balls are contained in the containing portions when the semiconductor package structure passes through the opening to be carried on the carrying plate.

According to an embodiment of the present invention, the carrying plate further has a protruding portion. The protruding portion protrudes from a top surface of the carrying plate, and each of the containing portions is a dent formed on the protruding portion. The bottom surface leans against a top surface of the protruding portion and the solder balls are respectively contained in the containing portions when the semiconductor package structure is carried on the carrying plate.

According to an embodiment of the present invention, the containing portions are arranged in an array or irregularly.

According to an embodiment of the present invention, the solder balls are arranged in an array and the containing portions are a plurality of trenches or slits formed on the carrying plate in parallel. The bottom surface leans against a top surface of the carrying plate and each of the containing portions contains a line of the solder balls when the semiconductor package structure is carried on the carrying plate.

According to an embodiment of the present invention, the solder balls are arranged in an array, the carrying plate further has a plurality of ribs parallel to one another, and each of the containing portions is a trench or a slit formed between adjacent two of the ribs. The bottom surface leans against the ribs and each of the containing portions contains a line of the solder balls when the semiconductor package structure is carried on the carrying plate. Herein, the ribs and the containing portions are parallel to a major axis of the body.

The present invention further provides a tape for carrying at least one of the above-mentioned semiconductor package structure. The tape comprises a body, at least a carrying plate and at least a side wall. The body has at least an opening. The carrying plate is capable of carrying the semiconductor package structure and has a plurality of protrusions, wherein the protrusions are distributed on a periphery of the carrying plate and adjacent to the side wall, and heights of the protrusions are larger than diameters of the solder balls. The side wall surrounds the carrying plate and connects between the body and the carrying plate, so as to form a containing space together with the carrying plate. The side surface leans against the side wall and the bottom surface leans against the protrusions when the semiconductor package structure passes through the opening to be contained in the containing space.

According to an embodiment of the present invention, the semiconductor package structure is just fit into the opening due to a shape of the opening is matched up with a contour of the bottom surface.

According to an embodiment of the present invention, the body further has a guiding portion. The guiding portion is disposed at one side or both sides of the body along a major axis of the body. Herein, the guiding portion consists of a row of apertures disposed at one side of the body or two rows of the apertures respectively disposed at two opposite sides of the body.

According to an embodiment of the present invention, each of the protrusions is a circular cylinder, an elliptic cylinder, a semi-circular cylinder, a semi-elliptic cylinder or a polygon pillar.

According to an embodiment of the present invention, a shape of the bottom surface and a contour of the carrying plate are polygons substantially the same to each other, and numbers of the protrusions adjacent to each side of the carrying plate are all equal.

Accordingly, when the semiconductor package structure is packed by the tape of the present invention, a relative movement therebetween in a horizontal direction is less likely to be formed. Therefore, the solder balls disposed on the bottom surface of the semiconductor package structure are less likely to be damaged or separated from the bottom surface due to being hit or pressed.

### BRIEF DESCRIPTION OF THE DRAWINGS

FIG. 1A illustrates a top view of a tape according to an embodiment of the present invention.

FIG. 1B illustrates a cross-sectional view of the tape along line A-A as shown in FIG. 1A.

FIG. 1C illustrates a cross-sectional view of the tape as shown in FIG. 1B carrying a semiconductor package structure.

FIG. 2A illustrates a top view of a tape according to another embodiment of the present invention.

FIG. 2B illustrates a cross-sectional view of the tape along line B-B as shown in FIG. 2A.

FIG. 2C illustrates a cross-sectional view of the tape as shown in FIG. 2B carrying a semiconductor package structure.

FIG. 3A illustrates a top view of a tape according to another embodiment of the present invention.

FIG. 3B illustrates a cross-sectional view of the tape along line C-C as shown in FIG. 3A.

FIG. 3C illustrates a cross-sectional view of the tape as shown in FIG. 3B carrying a semiconductor package structure.

FIG. 4A illustrates a top view of a tape according to another embodiment of the present invention.

FIG. 4B illustrates a cross-sectional view of the tape along line D-D as shown in FIG. 4A.

FIG. 4C illustrates a cross-sectional view of the tape as shown in FIG. 4B carrying a semiconductor package structure.

FIG. 5A illustrates a top view of a tape according to another embodiment of the present invention.

FIG. 5B illustrates a cross-sectional view of the tape along line E-E as shown in FIG. 5A.

FIG. 5C illustrates a cross-sectional view of the tape as shown in FIG. 5B carrying a semiconductor package structure.

FIG. 6A illustrates a top view of a tape according to another embodiment of the present invention.

FIG. 6B illustrates a cross-sectional view of the tape along line F-F as shown in FIG. 6A.

FIG. 6C illustrates a cross-sectional view of the tape as shown in FIG. 6B carrying a semiconductor package structure.

### DETAILED DESCRIPTION OF THE INVENTION

Reference will now be made in detail to specific embodiments of the present invention. Examples of these embodiments are illustrated in the accompanying drawings. While the invention will be described in conjunction with these specific embodiments, it will be understood that it is not intended to limit the invention to these embodiments. In fact, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations are not described in detail in order not to obscure the present invention.

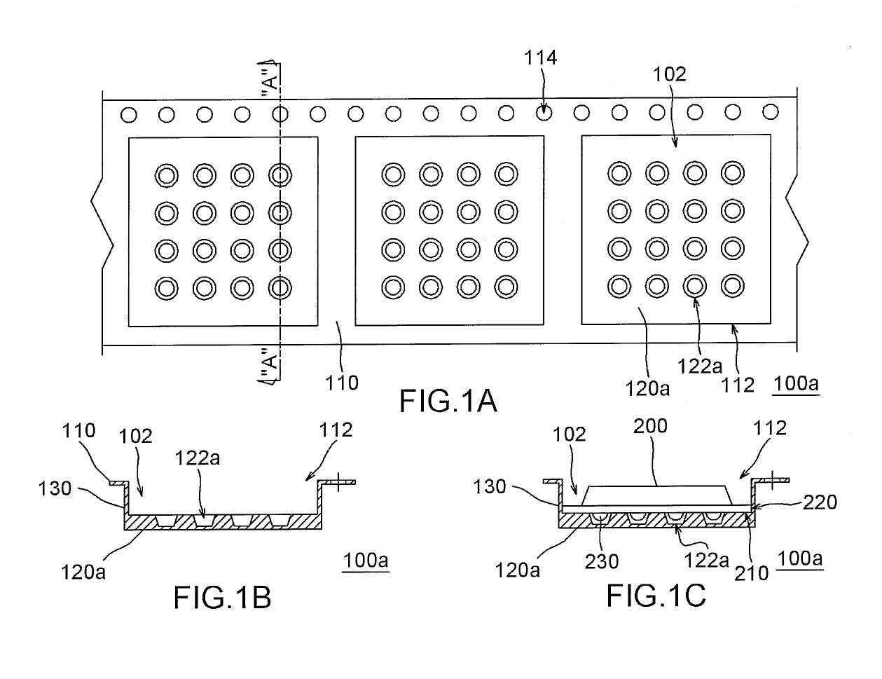

FIG. 1A illustrates a top view of a tape according to an embodiment of the present invention, and FIG. 1B illustrates a cross-sectional view of the tape along line A-A as shown in FIG. 1A. In addition, FIG. 1C illustrates a cross-sectional view of the tape as shown in FIG. 1B carrying a semiconductor package structure. Referring to FIGS. 1A and 1B, the tape 100a has at least a containing space 102, and each containing space 102 may contain a semiconductor package structure 200 as illustrated in FIG. 1C. The semiconductor package structure 200 in the present embodiment as shown in FIG. 1C may be a BGA semiconductor package structure, which has a bottom surface 210, a side surface 220 surrounding the bottom surface 210 and a BGA composed of a plurality of solder balls 230 disposed on the bottom surface 210. However, in other non-illustrated embodiments, there may also be a plurality of BGAs disposed on the bottom surface of the semiconductor package structure. Alternatively, the solder balls may be irregularly arranged on the bottom surface.

In the present embodiment, a body 110 of the tape 100a has at least an opening 112 (3 openings are illustrated in FIG. 1A as an example) and each of the openings 112 corresponds to a carrying plate 120a and a side wall 130, wherein a shape of the opening 112 is matched up with a contour of the bottom surface 210 of the semiconductor package structure 200, and thus the semiconductor package structure 200 is just fit into the opening 112. In addition, the carrying plate 120a may be used for carrying the semiconductor package structure 200 as illustrated in FIG. 1C and has a plurality of containing portions 122a. Here, each of the containing portions 122a is a dent formed on the carrying plate 120a, and the containing portions 122a are arranged in an array (16 containing portions as a 4×4 array are illustrated in FIG. 1A as an example) due to corresponding to the solder balls 230 in location one to one. Further, depths of the containing portions 122a are larger than heights of the corresponding solder balls 230, and widths of the containing portions 122a are larger than diameters of the corresponding solder balls 230. Besides, the side wall 130 surrounds the carrying plate 120a and connects between the body 110 and the carrying plate 120a, so as to form a containing space 102 together with the carrying plate 120a. In other non-illustrated embodiments, the containing portions corresponding to the solder balls in location may be arranged irregularly as well.

Next, referring to FIG. 1C, when the semiconductor package structure 200 passes through the opening 112 to be contained in the containing space 102 and carried on the carrying plate 120a, the side surface 220 leans against an inner surface of the side wall 130 and the solder balls 230 are respectively contained in the corresponding containing portions 122a. Note that the semiconductor package structure 200 contained in the containing space 102 is confined by the side wall 130 at this time, and thus difficult to move along a horizontal direction relative to the tape 100a. Therefore, the solder balls 230 disposed on the bottom surface 210 of the semiconductor package structure 200 are less likely to be damaged or separated from the bottom surface 210 due to being hit or pressed by the tape 100a. In addition, the semiconductor package structure 200 is supported well due to a top surface of the carrying plate 120a passing through gaps between the solder balls 230 to support the bottom surface 210 of the semiconductor package structure 200.

Furthermore, the body 110 as shown in FIG. 1A may further has a guiding portion 114. In the present embodiment, the guiding portion 114 may consist of a row of apertures disposed along a major axis of the body 110 at one side of the body 110, and thus the tape 100a may be driven by the tape winder (non-illustrated in all FIGs.) via the guiding portion 114 to move along the major axis of the body 110. Besides, the guiding portion in other non-illustrated embodiments may consist of two rows of apertures disposed at two opposite sides of the body as well. Alternatively, the guiding portion may be at least one of a guiding rail, a guiding trench or a serrated guiding edge according to the design of the tape winder.

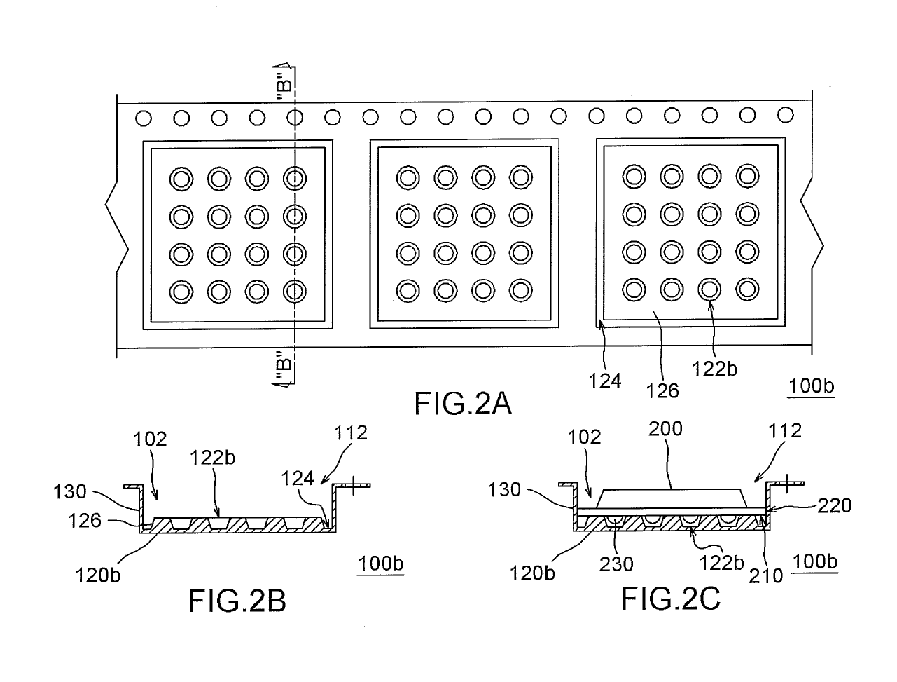

FIG. 2A illustrates a top view of a tape according to another embodiment of the present invention, and FIG. 2B illustrates a cross-sectional view of the tape along line B-B as shown in FIG. 2A. Further, FIG. 2C illustrates a cross-sectional view of the tape as shown in FIG. 2B carrying a semiconductor package structure. Referring to FIGS. 2A and 2B, the tape 100b in the present embodiment is similar to the tape 100a in the previous embodiment. The difference between the two embodiments is that the carrying plate 120a is thick enough to form the containing portion 122a thereon directly; however the carrying plate 120b is thinner, and thus a protruding portion 126 is formed on the top surface 124 of the carrying plate 120b first, and then a plurality of containing portions 122b are formed on the protruding portion 126.

Similarly, referring to the FIGS. 2B and 2C, when the semiconductor package structure 200 passes through the opening 112 to be contained in the containing space 102 and carried on the carrying plate 120b, the side surface 220 leans against the inner surface of the side wall 130 and the solder balls 230 are contained in the corresponding containing portions 122b respectively. Therefore, the semiconductor package structure 200 is difficult to move along a horizontal direction relative to the tape 100b at this time due to confined by the side wall 130, and thus the solder balls 230 are less likely to be hit or pressed by the tape 100b. In addition, the semiconductor package structure 200 is supported well due to the carrying plate 120b passing through gaps between the solder balls 230 to support the bottom surface 210 of the semiconductor package structure 200.

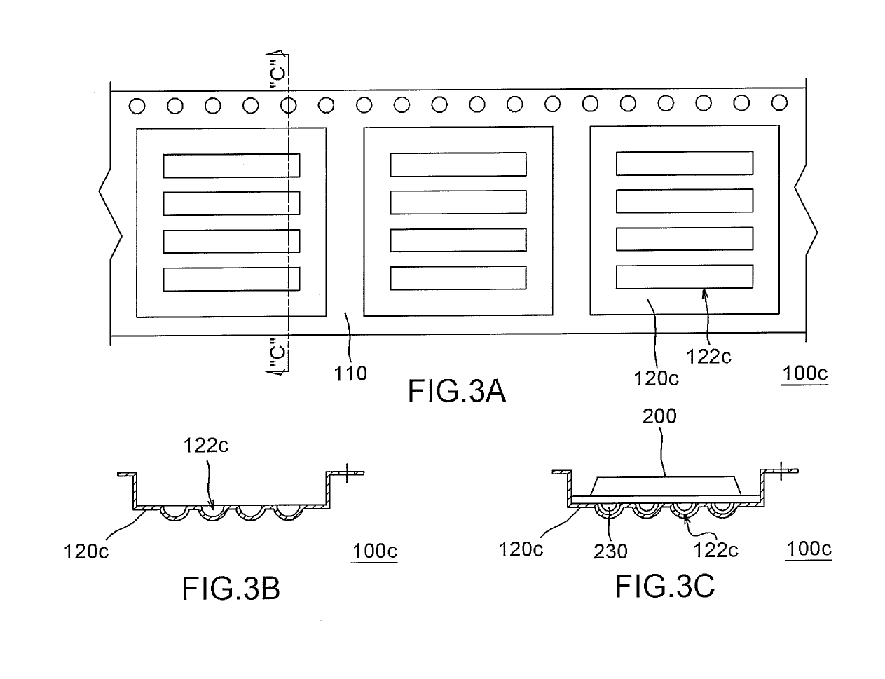

FIG. 3A illustrates a top view of a tape according to another embodiment of the present invention, and FIG. 3B illustrates a cross-sectional view of the tape along line C-C as shown in FIG. 3A. Further, FIG. 3C illustrates a cross-sectional view of the tape as shown in FIG. 3B carrying a semiconductor package structure. Referring to FIGS. 3A and 3B, the tape 100c in the present embodiment is similar to the tape 100b in the previous embodiment. The difference between the two embodiments is that the containing portions 122b of the tape 100b are formed on the protruding portion 126 after the protruding portion 126 is formed on the top surface 124 of the carrying plate 120b; however, a plurality of trenches parallel to one another are directly formed on the carrying plate 120c, for example by pressing, to be the containing portions 122c of the tape 100c. Therefore, referring to FIGS. 3B and 3C, each of the containing portions 122c contains a line of the solder balls 230 when the semiconductor package structure 200 is carried on the carrying plate 120c.

As shown in FIG. 3A, extension directions of the containing portions 122c in the present embodiment are parallel to the major axis of the body 110. However, the present invention is not limited to the present embodiment. For example, the extension directions of the containing portions 122c may also be perpendicular to the major axis of the body 110. Alternatively, the extension directions of the containing portions 122c may also be parallel to a diagonal direction of the BGA.

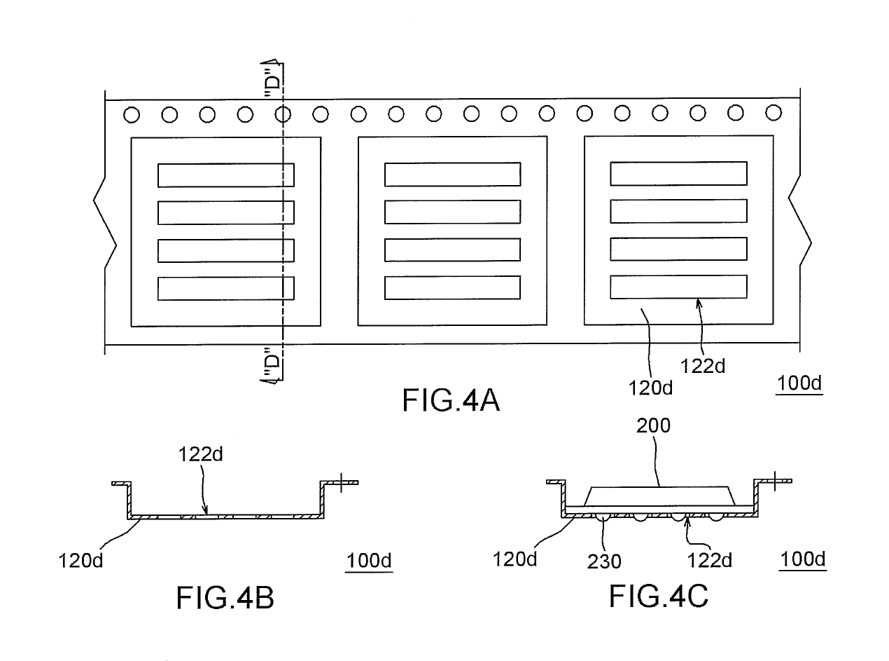

FIG. 4A illustrates a top view of a tape according to another embodiment of the present invention, and FIG. 4B illustrates a cross-sectional view of the tape along line D-D as shown in FIG. 4A. Further, FIG. 4C illustrates a cross-sectional view of the tape as shown in FIG. 4B carrying a semiconductor package structure. Referring to FIGS. 4A and 4B, the tape 100d in the present embodiment is similar to the tape 100c in the previous embodiment. The difference between the two embodiments is that the containing portions 122c on the carrying plate 120c are trenches; however, the containing portions 122d on the carrying plate 120d are slits. Therefore, referring to FIGS. 4B and 4C, each of the containing portions 122d contains a line of the solder balls 230 when the semiconductor package structure 200 is carried on the carrying plate 120d.

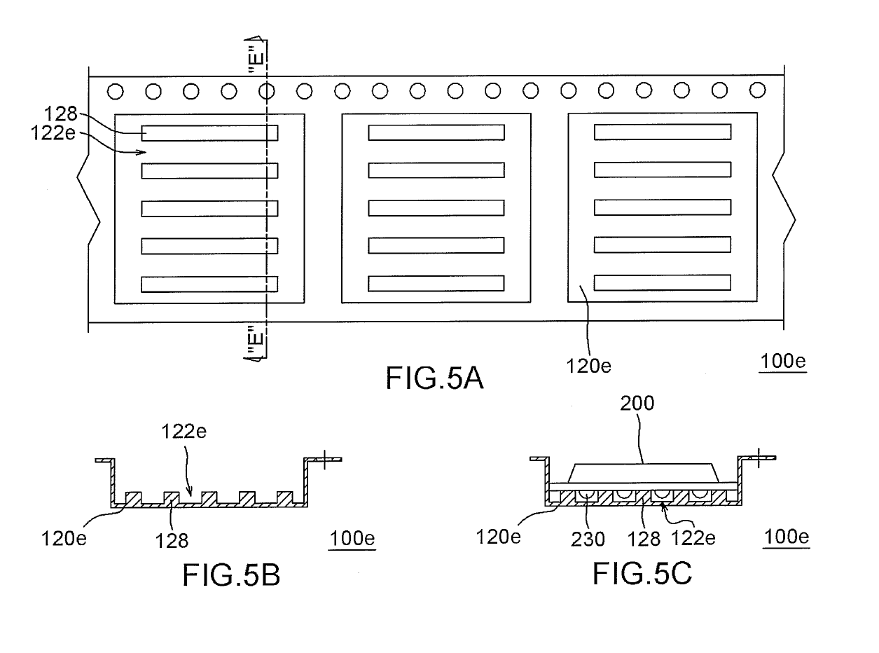

FIG. 5A illustrates a top view of a tape according to another embodiment of the present invention, and FIG. 5B illustrates a cross-sectional view of the tape along line E-E as shown in FIG. 5A. Further, FIG. 5C illustrates a cross-sectional view of the tape as shown in FIG. 5B carrying a semiconductor package structure. Referring to FIGS. 5A and 5B, the tape 100e in the present embodiment is similar to the tape 100c in the previous embodiment. The difference between the two embodiments is that, to the carrying plate 120c, the trenches are directly formed thereon to be the containing portions 122c; however, to the carrying plate 120e, there is a plurality of ribs 128 formed thereon, and the trenches are respectively formed between every two adjacent ribs 128 to be the containing portions 122e. Furthermore, in other non-illustrated embodiments, there may be a plurality of slits respectively formed between every two adjacent ribs to be the containing portions as well. Similarly, referring to FIGS. 5B and 5C, each of the containing portions 122e contains a line of the solder balls 230 when the semiconductor package structure 200 is carried on the carrying plate 120e. In addition, the extension directions of the ribs and the trenches or the slits may also be perpendicular to the major axis of the body or parallel to the diagonal direction of the BGA.

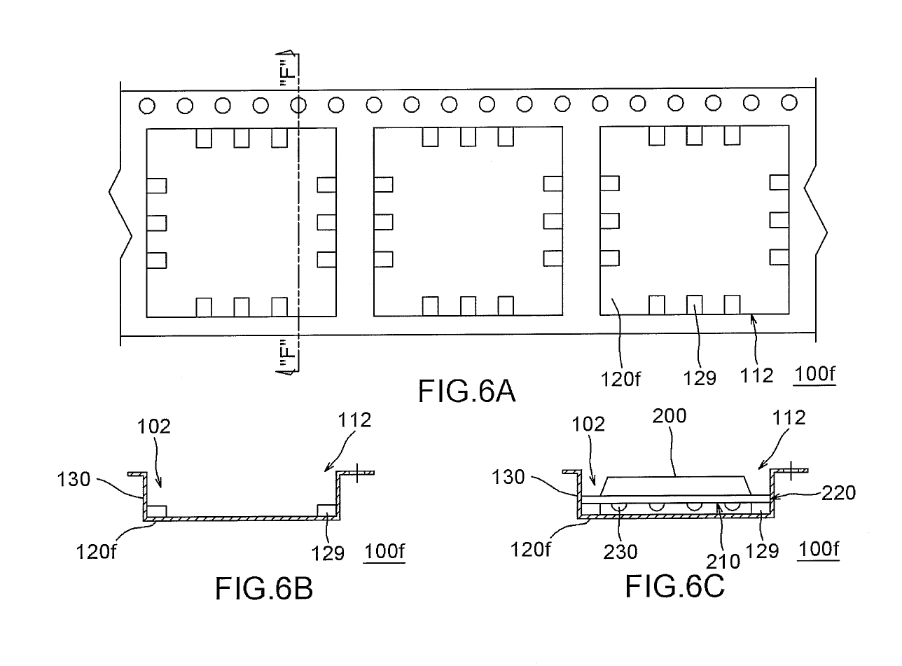

FIG. 6A illustrates a top view of a tape according to another embodiment of the present invention, and FIG. 6B illustrates a cross-sectional view of the tape along line F-F as shown in FIG. 6A. Further, FIG. 6C illustrates a cross-sectional view of the tape as shown in FIG. 6B carrying a semiconductor package structure. Referring to FIGS. 6A to 6C, the tape 100f in the present embodiment is similar to the tape 100a in the previous embodiment. The difference between the two embodiments is that the tape 100a carries the semiconductor package structure 200 with the top surface of the carrying plate 120a and contains the solder balls 230 in the containing portions 122a; however, the tape 100f carries the semiconductor package structure 200 with a plurality of protrusions 129 formed on the top surface of the carrying plate 120f and contains the solder balls 230 in a gap between top surfaces of the protrusions 129 and the top surface of the carrying plate 120f.

In the present embodiment, the protrusions 129 may respectively be a circular cylinder, an elliptic cylinder, a semi-circular cylinder, a semi-elliptic cylinder, a polygon pillar or a pillar with any contour, which are distributed on a periphery of the carrying plate 120f and abut the side wall 130, and heights thereof are larger than diameters of the solder balls 230. In detail, a shape of the bottom surface 210 of the semiconductor package structure 200 and a contour of the carrying plate 120f are substantially the same squares, and each edge of the carrying plate 120f is equipped with three protrusions 129 in equidistance. Therefore, the side surface 220 of the semiconductor package structure 200 leans against the side wall 130 and the bottom surface 210 of the semiconductor package structure 200 is carried on the protrusions 129 when the semiconductor package structure 200 passes through the opening 112 to be contained in the containing space 102.

In summery, when using the tape of the present invention to pack the semiconductor package structure, the semiconductor package structure is carried on the carrying plate and the side surface thereof leans against the side wall, and thus a relative movement between the semiconductor package structure and the tape in a horizontal direction is less likely to be formed. Therefore, the solder balls disposed on the bottom surface of the semiconductor package structure may be steadily contained in the containing portion and are less likely to be damaged or separated from the bottom surface due to being hit or pressed.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A tape for carrying at least a semiconductor package structure having a bottom surface, a side surface surrounding the bottom surface and a plurality of solder balls disposed on the bottom surface, comprising:
a body having at least an opening;
at least a carrying plate for carrying the semiconductor package structure and having a plurality of containing portions; and
at least a side wall surrounding the carrying plate and connecting between the body and the carrying plate, wherein the side surface leans against the side wall and the solder balls are contained in the containing portions when the semiconductor package structure passes through the opening to be carried on the carrying plate.

2. The tape as claimed in claim 1, wherein the semiconductor package structure is just fit into the opening due to a shape of the opening is matched up with a contour of the bottom surface.

3. The tape as claimed in claim 1, wherein the body further has a guiding portion disposed at one side or both sides of the body along a major axis of the body.

4. The tape as claimed in claim 3, wherein the guiding portion consists of a row of apertures disposed at one side of the body or two rows of the apertures respectively disposed at two opposite sides of the body.

5. The tape as claimed in claim 1, wherein the carrying plate further has a protruding portion protruding from a top surface of the carrying plate, and each of the containing portions is a dent formed on the protruding portion, the bottom surface leans against a top surface of the protruding portion and the solder balls are respectively contained in the containing portions when the semiconductor package structure is carried on the carrying plate.

6. The tape as claimed in claim 1, wherein the containing portions are arranged in an array or irregularly.

7. The tape as claimed in claim 1, wherein the solder balls are arranged in an array and the containing portions are a plurality of trenches or slits formed on the carrying plate in parallel, the bottom surface leans against a top surface of the carrying plate and each of the containing portions contains a line of the solder balls when the semiconductor package structure is carried on the carrying plate.

8. The tape as claimed in claim 1, wherein the solder balls are arranged in an array, the carrying plate further has a plurality of ribs parallel to one another, and each of the containing portions is a trench or a slit formed between adjacent two of the ribs, the bottom surface leans against the ribs and each of the containing portions contains a line of the solder balls when the semiconductor package structure is carried on the carrying plate.

9. The tape as claimed in claim 8, wherein the ribs and the containing portions are parallel to a major axis of the body.

10. A tape for carrying at least a semiconductor package structure having a bottom surface, a side surface surrounding the bottom surface and a plurality of solder balls disposed on the bottom surface, comprising:
a body having at least an opening;
at least a carrying plate for carrying the semiconductor package structure and having a plurality of protrusions, wherein the protrusions are distributed on a periphery of the carrying plate and heights of the protrusions are larger than diameters of the solder balls; and
at least a side wall surrounding the carrying plate and connecting between the body and the carrying plate, so as to form a containing space together with the carrying plate, and the protrusions are adjacent to the side wall, wherein the side surface leans against the side wall and the bottom surface leans against the protrusions when the semiconductor package structure passes through the opening to be contained in the containing space.

11. The tape as claimed in claim 10, wherein the semiconductor package structure is just able to pass through the opening due to a shape of the opening is matched up with a contour of the bottom surface.

12. The tape as claimed in claim 10, wherein the body further has a guiding portion disposed at one side or both sides of the body along a major axis of the body.

13. The tape as claimed in claim 12, wherein the guiding portion consists of a row of apertures disposed at one side of the body or two rows of the apertures respectively disposed at two opposite sides of the body.

14. The tape as claimed in claim 10, wherein each of the protrusions is a circular cylinder, an elliptic cylinder, a semi-circular cylinder, a semi-elliptic cylinder or a polygon pillar.

15. The tape as claimed in claim 10, wherein a shape of the bottom surface and a contour of the carrying plate are polygons substantially the same to each other, and numbers of the protrusions adjacent to each side of the carrying plate are all equal.
